(19) United States
(12) Patent Application Publication
(10) Pub. No.: US 2005/0233587 A1
(43) Pub. Date: Oct. 20, 2005

(54) Method for making an anisotropic conductive film pointed conductive inserts

(76) Inventors: Francois Baleras, Seysinet (FR); Pierre Renard, Grenoble (FR); Cyrille Rossat, Grenoble (FR)

Correspondence Address: Thelen Reid & Priest, PO Box 640640, San Jose, CA, 95164-0640, US

(21) Appl. No.: 10/520,338

(22) PCT Filed: Jul. 2, 2003
(86) PCT No.: PCT/FR03/02056

§ 371 Date: Jan. 4, 2005

(30) Foreign Application Priority Data
Jul. 5, 2002 (FR) 02/08451

(51) Int. Cl. H01L 21/302

(52) U.S. Cl. 438/689

(57) ABSTRACT

The invention relates to a method for making an anisotropic conductive film with pointed conductive inserts.

The method comprises the etching of at least one pattern (C1, K1) in a single crystal substrate (15) in order to form at least one cell (22, 26) with a bottom intended for drawing the contour of an end of an insert (23, 27). The drawing of the pattern is for having at least one protruding tip appear in the bottom of the cell during the etching of the pattern along the (100) crystallographic plane of the substrate with limiting (111) or (110) planes of the pattern. The invention is applied to microconnector technology.

### TECHNICAL FIELD AND PRIOR ART

The present invention relates to a method for making an anisotropic conductive film with sharp conductive inserts.

In the field of microconnector technology, there are several large families of techniques for connecting chips and integrated circuits to an interconnection substrate: microwiring, connection by tape automated bonding (TAP), connection by beads (flip-chip technique) and the anisotropic conductive film (ACF) technique. According to the microwiring technique, connection is achieved through gold or aluminum wires. The TAB connection uses an intermediate strip including a network of metal conductors. According to the flip-chip technique, the input/output pads are connected through brazes (fusible beads). The ACF technique applies conductive films consisting of metal particles incorporated into an insulating film or of metal inserts included into an insulating film. The intended electrical bonds between an interconnection substrate and a chip are then established by thermocompression, by placing the conductive films between the substrate and the chip.

FIGS. 1A-1F, 2, 3A-3C illustrate a known method for making a conductive film with sharp inserts disclosed in French Patent No. 2,766,618.

A first step of the method consists of etching a substrate 1, for example a silicon substrate. For this, a planar face 2 of a substrate 1 with the (110) crystallographic plane is covered with a silicon nitride or gold mask 3. The mask 3 is etched by a lithographical technique so that the planar face 2 of the substrate appears through apertures 4 (cf. FIG. 1A). The exposed portions of the planar face 2 then receive a chemical etching, for example by using KOH, along the (111) crystallographic planes. Cells 5 are thereby formed (cf. FIG. 1B). What remains of mask 3 is then removed and deposition of a conductive sacrificial layer 6 on the etched face of the substrate (cf. FIG. 1C) is performed. The layer 6 may be made in copper (Cu), titanium (Ti), nickel (Ni), or tin/lead (SnPb). The thickness of the layer 6, for example between 0.1 and 0.3 μm, conforms to the profile of the etched face. A polymer layer 7, for example a polyimide layer with a thickness of 10 μm, is deposited on the sacrificial layer 6. The polymer layer 7 is etched by photolithography in order to form holes 8 in the extension of the cells 5 (cf. FIG. 1D).

Metal inserts 9 are formed from the bottom of the cells 5 up to the upper face of the polymer layer 7 (cf. FIG. 1E), by electrolytic growth, using the sacrificial layer 6 as an electrode. The last step consists of chemically etching the metal layer 6 in order to obtain detachment of the insulating film 7 provided with the conductive inserts 9 (cf. FIG. 1F).

The etching of the silicon substrate 1 is carried out so that the cells 5 are of a pyramidal shape with a square section. Accordingly, the inserts 9 are provided with tips 10. Moreover, the holes 8 have a circular cross-section with a smaller size than the cross-section of the cells 5 at the face 2 of the substrate. The inserts 9 are then embedded into the insulating film 7 as illustrated in FIG. 2.

A drawback of the method for making an anisotropic conductive film described above, is that it only allows the making of inserts provided with a single tip. If the intention is to make inserts provided with two tips (one at each end of the insert), the making method needs to be changed beyond the step which leads to the formation of a structure as illustrated in FIG. 1D. This change in the method is illustrated in FIGS. 3A-3C. A mask 11 is then positioned at a predetermined distance d above the insulating film 7. The mask 11 is provided with holes 12 positioned facing the holes 8 (cf. FIG. 3A). The metal for forming the inserts is then sprayed or evaporated through the holes 12 of the mask. The distance d which separates the mask 12 from the insulating film and the diameter of the holes of the mask 12 are selected so as to give a pointed shape 13 (cf. FIG. 3B) to the ends of the inserts located on the side of the mask. Subsequently, detachment of the insulating film 7 is performed by chemical etching of the conducting layer 6, for example with hydrofluoric acid. The outcome of this is an anisotropic conductive film 7 provided with inserts 14 with a tip at each end (cf. FIG. 3C).

Advantageously, with the alternative method of the known art mentioned above, the inserts may be made with two pointed ends. A drawback of this alternative however lies in the fact that a mask provided with holes must be placed above the film very accurately. The use of such a mask then limits the pitch of the inserts to about 50 μm.

The invention does not have the above drawbacks.

### DISCUSSION OF THE INVENTION

Indeed, the invention relates to a method for making an anisotropic conductive film with conductive inserts, the method comprising the etching of a least one pattern in a single crystal substrate in order to form at least one cell with a bottom for drawing the contour of a first end of an insert. The drawing of the pattern is intended for having at least one protruding tip and at least one recessed area appear in the bottom of the cell, during the etching of the pattern along at least one crystallographic plane of the substrate with limiting crystallographic planes.

By protrusion, a pointed area of the substrate is meant, pointing upwards as opposed to a recessed area of the substrate which points downwards to the bottom of the substrate.

The inserts obtained according to the method of the invention are dissymmetrical. Thus, an insert formed from the cell at the end opposite to its first end has at least one protruding tip and at least one recessed area, the protruding portion and the recessed area facing a recessed area and a protruding tip of the first end of the insert, respectively.

According to a particular embodiment, the crystallographic plane along which the pattern is etched, is the (100) plane and the limiting crystallographic planes are the (111) and (110) planes.

Advantageously, with the making method according to the invention, conductive inserts with very small dimensions, spaced apart with a very small pitch (typically 1 to 2 μm inserts may be spaced apart by 4 to 5 μm) may be obtained. Advantageously, the inserts may have several tips at each end, thereby promoting electrical contact between the components to be assembled.

Advantageously, the method is simple and reproducible. Metal inserts are preferentially made by electrolysis. With this method, the shape of the inserts is directly linked to the topology of the cell formed in the substrate. It is also possible to make the insert by spraying or evaporating metal.

The topology of the cell in which are formed the inserts, is obtained by etching patterns at the surface of a substrate. The layout of the patterns is preferentially selected so as to provide electrolytic growth capable of developing tips at both ends of the inserts.

The substrate consists of single crystal material for which wet etching is anisotropic (i.e. for which the etching rate depends on the crystal planes). For example silicon (Si) or silicon carbide (SiC) may be mentioned.

The parameters to be defined for obtaining a cell topology according to the invention are: the shape of the patterns, the orientation of the patterns relatively to the directions of the crystallographic planes, and, in the case of several patterns, the mutual arrangement of the patterns. A cell may be made, for example, from a group of simple patterns, from a truncated square, from several groups of simple patterns or even from several groups of truncated squares.

For example, a group of simple patterns may consist of at least four simple patterns, for example four circles or four squares, specifically positioned and orientated. A simple pattern is etched along the (100) crystallographic plane with limiting (111) or (110) planes. During the etching, the pattern is widened either because of the geometry of the pattern (for example, in the case of a circle) or by the orientation of the pattern relatively to the <110> direction of the crystal lattice (the case of deforming squares), or because of the overetching phenomenon (etching under a mask).

The selected arrangement of simple patterns results in the widening of the patterns allowing them to join. When the patterns join, anisotropic wet etching uncovers new crystal planes other than the limiting (111) and (110) planes. Etching of the area surrounded by the simple patterns then starts. As this area includes limiting (111) and (110) crystal planes and non-limiting planes, a pointed topology is created.

Hence, the etching of a substrate mainly consists of two phases. A first phase is a phase during which the patterns are etched independently of each other. The second phase (related to the shape and to the positioning of the patterns) is a phase during which the etchings of the patterns join and etching of the area surrounding the patterns starts. With this time lag between the first and second phases, a topology with tip(s) may be achieved in the cavities.

### SHORT DESCRIPTION OF THE FIGURES

Other features and advantages of the invention will become apparent from the description of a preferential embodiment made with reference to the appended figures, wherein:

FIGS. 1A-1F and 2 illustrate different steps of a method for making an anisotropic conductive film with pointed inserts according to the prior art;

FIGS. 3A-3C illustrate an alternative to the making method illustrated in FIGS. 1A-1F and 2;

FIGS. 4A-4F illustrate different steps of a first embodiment of the method for making an anisotropic conductive film with pointed inserts according to the invention;

FIGS. 5A-5D, 6, 7, 8 and 9 illustrate examples of patterns for obtaining pointed inserts according to the method of the invention;

FIGS. 10A-10F illustrate different steps of a second embodiment of the method for making an anisotropic conductive film according to the invention;

FIGS. 11A-11B and 12A-12B illustrate examples of pointed inserts as well as examples of the positioning of pointed inserts in an insulating film according to the invention.

In all the figures, the same references designate the same components.

### DETAILED DESCRIPTION OF EMBODIMENTS OF THE INVENTION

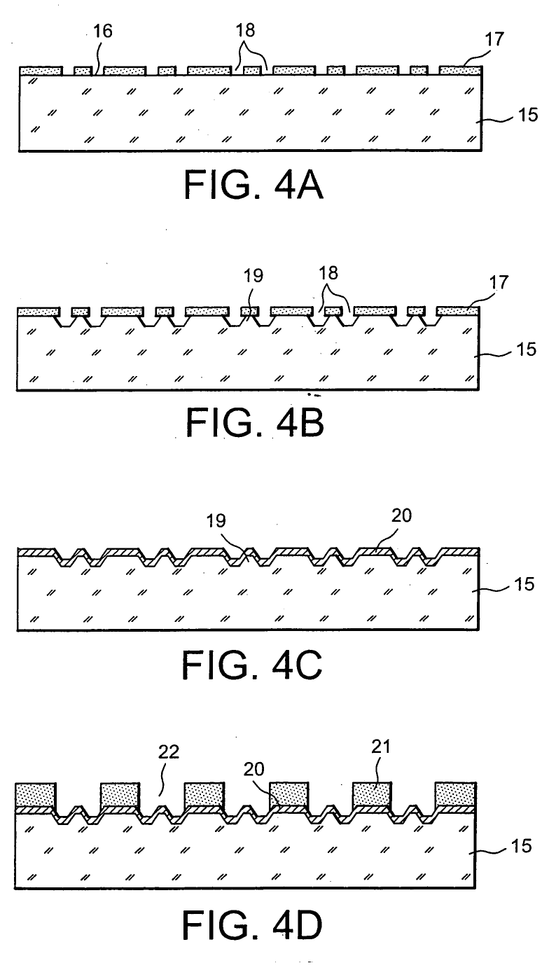

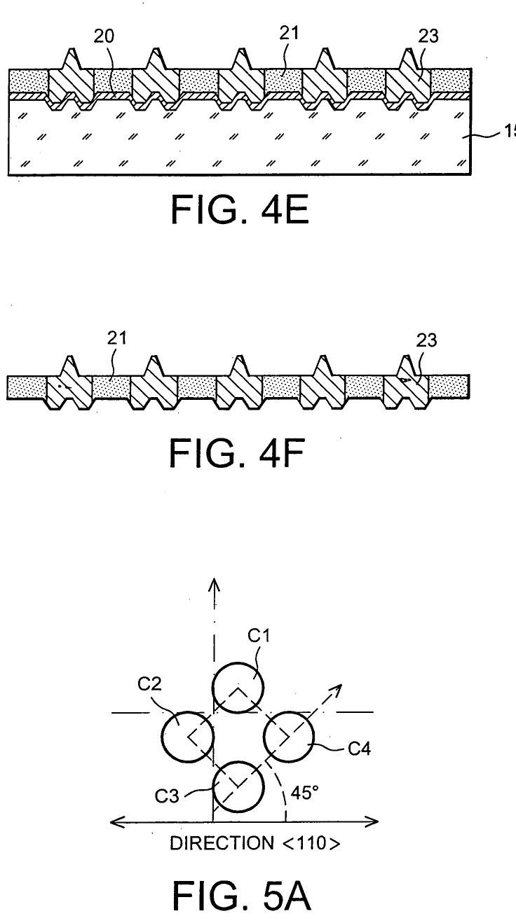

FIGS. 4A-4F illustrate different steps of a first embodiment of the method for making an anisotropic conductive film according to the invention.

The first step of this method consists of etching a silicon substrate 15, for example. For this, the planar face 16 of the substrate 15 with a (110) crystallographic plane, is covered with a mask 17 in silicon nitride, gold, copper, or any other material compatible with anisotropic wet etching. The mask 17 is etched with a lithographic technique, so that the face 16 of the substrate 15 appears through the apertures 18 (FIG. 4A). The exposed portions of the planar face 16 then receive a chemical etching (for example by using KOH) along the (111) crystallographic planes. Cells 18 including tips 19 (cf. FIG. 4B) are obtained.

What remains of the mask 17 is then removed and deposition of a sacrificial, for example conductive, layer 20 is performed on the etched face 16 of the substrate 15 (cf. FIG. 4C). The layer 20 conforms to the profile of the etched face 16. It may be made in Cu, Ti, Ni or SnPb. Its thickness is between 0.1 and 3 μm for example.

A polymer layer 21 (for example a polyimide layer with a thickness of 10 μm) is coated onto the metal layer 20 by a photolithographic technique, the layer 21 is etched in order to form circular holes 22 therein, aligned with the tips 19 of the substrate 15 (cf. FIG. 4D).

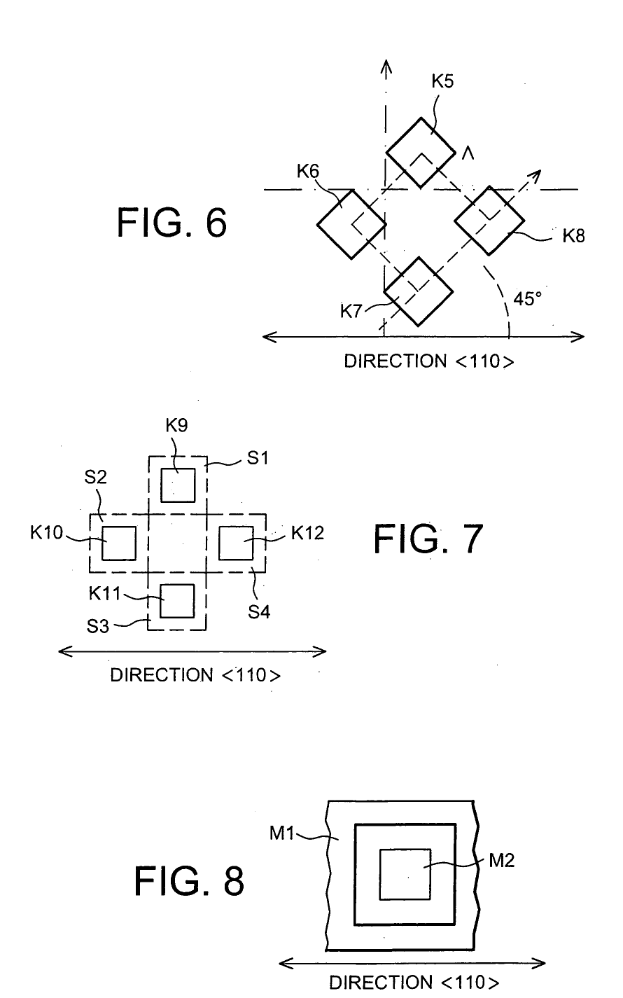

Metal inserts 23 are formed from the bottom of the cells up to the upper face of the polymer layer 21, in one step by electrolytic growth, using the metal layer 19 as an electrode, and by filling the holes 22 (cf. FIG. 4E). The metal which forms the metal inserts 3 may for example be nickel or copper (FIG. 6E).

The last step consists of chemically etching the metal layer 20 in order to obtain detachment of the insulating film 21 provided with the inserts 23 (cf. FIG. 4F).

The holes 22 made in the insulated film 15 are of a circular cross-section. The cross-section of the holes 22 is less than the cross-section of the cells at the face 16 of the substrates 15, so that the inserts are embedded into the insulating film 15.

Wet etching may be completed with anisotropic etching (plasma etching) in order to enhance the height of the tips.

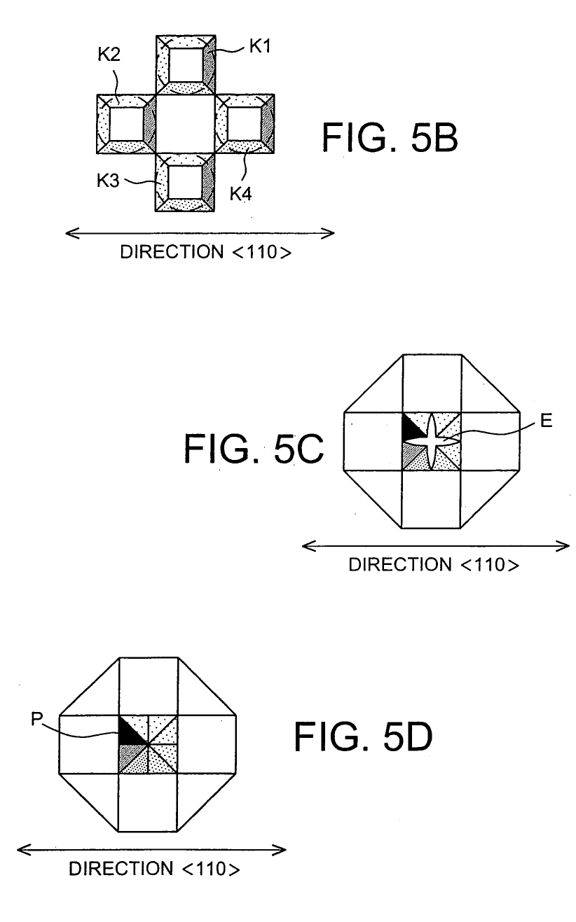

FIGS. 5A-5B, 6, 7, 8 and 9, illustrate examples of patterns for obtaining pointed inserts according to the method of the invention.

FIG. 5A illustrates a first pattern example for making tips in the substrate. The pattern consists of four circles C1, C2, C3, C4 mutually positioned so that their centres define a square. The axis passing through the centres of two circles which define a side of the square forms a non-zero angle, for example equal to 45°, with the <110> direction of the crystal lattice. FIG. 5B illustrates the formation of a cavity by anisotropic wet etching (for example a KOH-based etching) from the pattern illustrated in FIG. 5A. The four circles C1, C2, C3, C4, are transformed into four squares K1, K2, K3, K4, respectively, the angles of which join (cf. FIG. 5B). FIG. 5C illustrates the time course of the etching at the centre of the four circles with the occurrence of a star-shaped unetched area E having several slanted planes. Progression of the etching leads to the formation of a tip P provided with edges protruding from the etched area (cf. FIG. 5D). The etching of the areas surrounding the central area is not illustrated in FIGS. 5C and 5D.

FIG. 6 illustrates another pattern example, consisting of four squares, the sides of which are not orientated along the <110> axis of the crystal lattice.

Preferentially, the four squares K5, K6, K7, K8, are set up in order to form together a square pattern, each square with a side at an angle of 45° relatively to the <110> direction of the crystal lattice. The anisotropic wet etching of the four squares provides four square cavities, the length of each square cavity being equal to the side of the initial square multiplied by \sqrt{2}. The etching of the squares leads to the formation of cavities, the angles of which join, and which form a protruding tip in their centre.

FIG. 7 illustrates a second pattern example formed on the basis of four squares. The four squares K9, K10, K11, K12, are set up so as to form together a cross pattern, each square having two sides parallel to the <110> direction of the crystal lattice. Overetched areas S1, S2, S3, S4, surround the squares and enable the latter to join. The distance between two squares depends on the depth of the desired overetching.

FIG. 8 illustrates a truncated square pattern made on the basis of two masked areas M1, M2. Two parallel sides of the square are parallel to the <110> crystallographic direction of the substrate. A first masked area M1 defines a square aperture, in which a second masked area M2 is placed, also with a square shape, centered in the aperture defined by the masked area M1. Etching is then performed between the masked areas M1 and M2 and completed with the formation of a tip centered in the M2 area and protruding from the etching area.

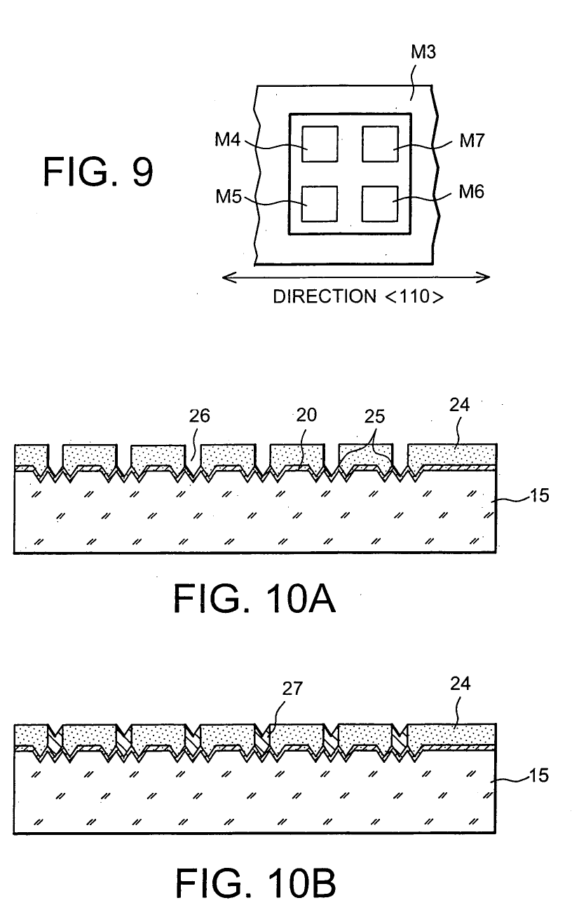

FIG. 9 illustrates a pattern example for the formation of an insert with multiple tips. The pattern is formed with four truncated squares. It is achieved on the basis of five masked areas. A first masked area M3 defines a square aperture in which four other masked areas M4, M5, M6, M7, are placed. The four masked areas M4, M5, M6, M7, are positioned as a square. The etching of the unmasked substrate then generates a cavity which includes four tips protruding from the etched area.

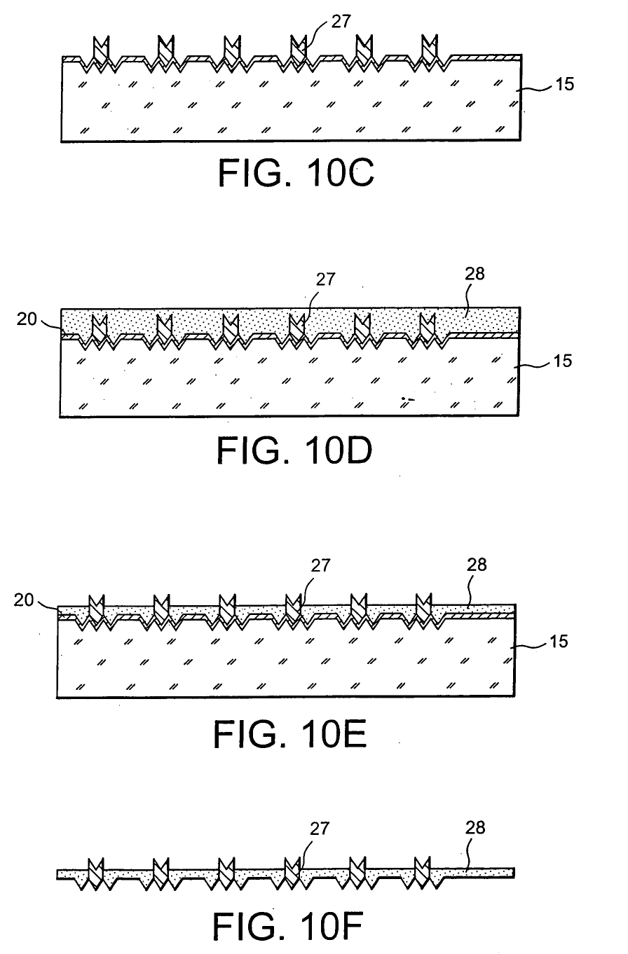

FIGS. 10A-10F illustrate different steps of a second embodiment of the method for making an anisotropic conductive film according to the invention.

Up to the step for depositing a sacrificial layer, the method according to the second embodiment of the invention includes the same steps as the method described earlier, i.e.: etching of a mask covering the substrate, chemical etching of the exposed substrate along determined crystallographic planes, removal of the mask and deposition of a sacrificial layer.

Only the steps after the step for depositing the sacrificial layer will now be described. A photoresist 24 is insolated through a mask in order to form holes 26 in the extension of the tips 25 formed in the cells of the substrate (cf. FIG. 10A). Metal inserts 27 are made preferentially by electrolysis (cf. FIG. 10B) through the holes 26 of the resin.

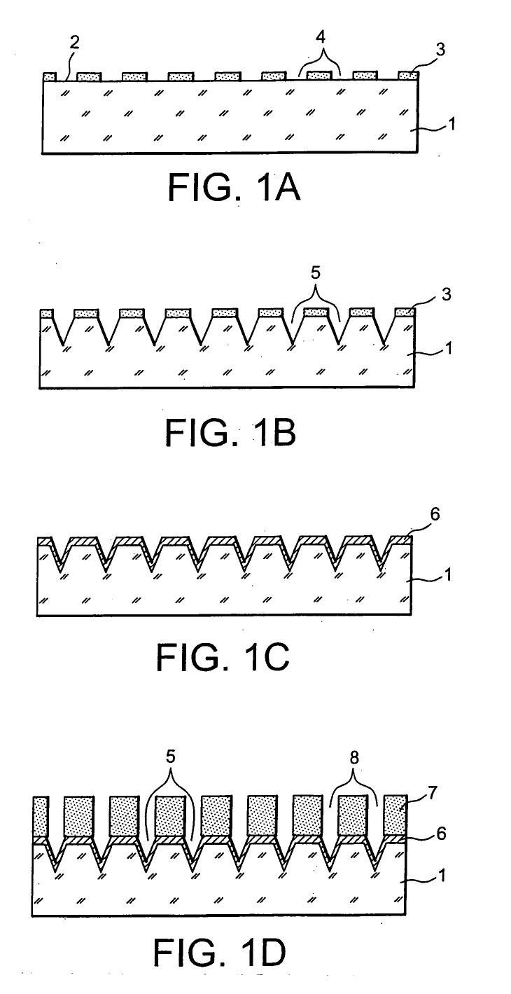

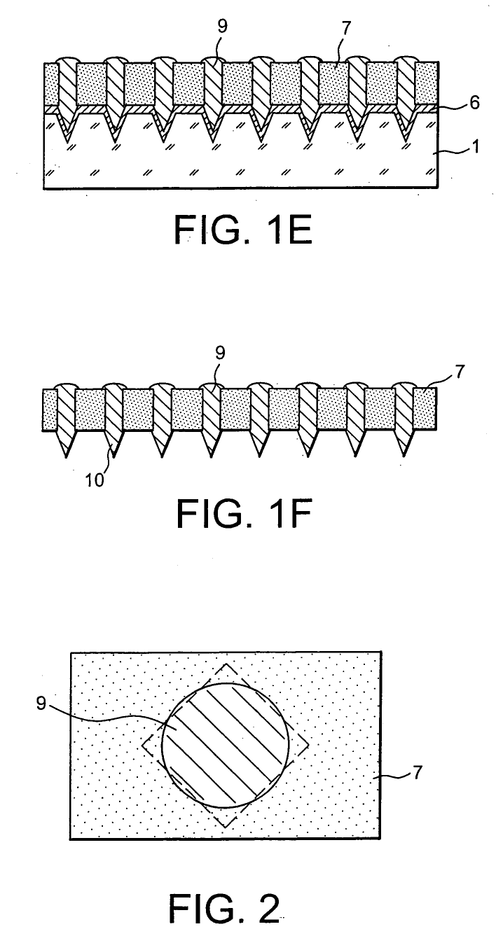

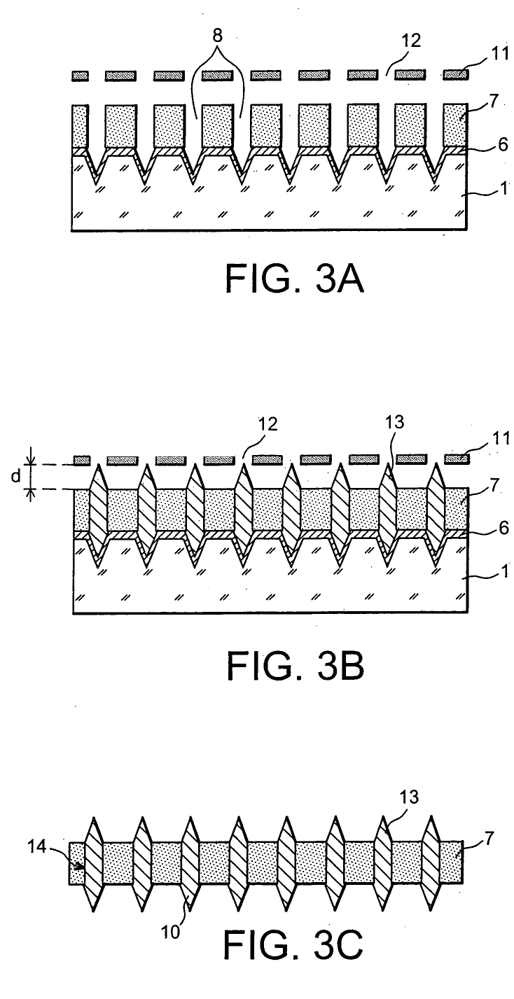

Once the metal inserts are made, the resin is removed by dissolving it in a solvent (cf. FIG. 10C). An insulating film 28 is then deposited by known methods of microelectronics onto the metal layer 20 and the inserts 27 (cf. FIG. 10D). With plasma etching of the insulating film 28, it is possible to bring out the tips of the inserts (cf. FIG. 1E). The insulating film 28 is then detached (cf. FIG. 10F) for example with hydrofluoric acid.

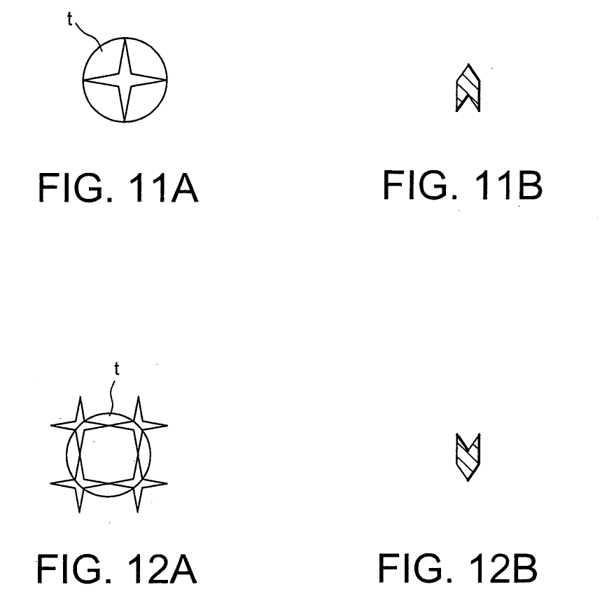

FIGS. 11A-11B and 12A-12B illustrate exemplary embodiments of inserts according to the invention, as well as the positioning of these inserts in insulating film holes. FIGS. 11A-11B illustrate an insert with one tip and FIGS. 12A-12B illustrate an insert with four tips. The cross-shaped inserts are placed in holes t of the insulating film.

There are several alternatives for some of the steps of the method of the invention. For example, the filling of the cells formed in the substrate may be achieved not only by electrolytic growth as mentioned above, but also by spraying or evaporating metal. In both latter cases, the metal deposited on the surface of the photoresist must then be removed. Several techniques are then possible, such as for example, mechanical lapping or mechano-chemical polishing.

According to the second embodiment of the invention, it is also possible to first deposit the photoresist between the inserts and then the isolated film. The sacrificial layer is then etched and the photoresist is dissolved. It is also possible to dissolve the photoresist in order to detach the anisotropic conductive film. With the latter alternative, the jutting out of the tips of the inserts relatively to the insulating film may be enhanced.

By using silicon as a substrate, a perfectly defined and very sharp tip is obtained, providing a very high quality of electrical contact on an aluminium pad.

When using a non-thermoplastic polymer for forming the insulating film, a slight spacing between the film and the chip to be connected, may be maintained with the tips of the inserts, leaving the possibility of using an adhesive film on all the surfaces to be contacted and therefore excellent mechanical strength.

Regardless of its embodiment, the method for making an anisotropic conductive film with pointed inserts according to the invention enables the size of the inserts to be highly lowered, typically a diameter from 1 to 2 μm for a pitch from 4 to 5 μm. This provides interconnection of chips the inputs/outputs of which have a very small pitch.

Also, regardless of the embodiment, the etching step applied in the method according to the invention may be completed by a further etching step for enhancing the heights of the tips. For example the further etching step may be purely anisotropic etching (plasma etching) or purely isotropic etching (wet etching). This etching may be achieved before or after the first etching. The basic pattern may be of any shape, as long as a less rapidly etched central area may be obtained.

The method according to the invention leads to the formation of a topology where the substrate has hollow areas with a very marked pointed shape. Advantageously, these hollow areas with a very marked pointed shape, allow very pointed metal inserts to be obtained during the electrolysis, and this not only on the side where the insert has a hollow portion, but also on the other side. Indeed, the growth of metal inserts by electrolysis is enhanced by the presence of the strong topology of the substrate. If the resin pattern is centered on a tip, the tip effect (faster growth related to current lines) enhances and maintains the topology of the substrate. If the resin pattern is surrounded by four tips, a similar effect is obtained during the electrolysis.

Advantageously, the ends of the conductive inserts are made in a hard material (for example nickel) . This allows its ends to be able to pierce through the oxide layer covering the pad to be connected. The inserts may also be entirely made in this hard material. As an alternative, only the extending-out portions of the inserts may be made in hard material.

The insulating film may be a thermoplastic polymer film or a multilayer film, the external layers of which are thermoplastic. With this, a self-adhesive function may be imparted to it during the assembly. In the opposite case, the insulating film must be provided with an adhesive layer before assembly.

The anisotropic conductive film obtained by the method of the invention, enables a chip or an integrated circuit to be directly mounted on an interconnection substrate, without it being necessary to specifically treat the pads of the chip or integrated circuit.

1. A method for making an anisotropic conductive film with conductive inserts, the method comprising the etching of at least one pattern (C1, K1) in a single crystal substrate (15) in order to form at least one cell (22, 26) with a bottom for drawing the contour of a first end of an insert (23, 27), characterized in that the drawing of the pattern is intended for having at least one protruding tip and at least one recessed area appear in the bottom of the cell, during the etching of the pattern along at least one crystallographic plane of the substrate with limiting crystallographic planes.

2. The method according to claim 1, characterized in that the crystallographic plane along which the pattern is etched, is the (100) plane and the limiting crystallographic planes are the (111) and (110) planes.

3. The method according to claim 1, characterized in that a pattern is formed with a set of elementary patterns separated from each other and positioned relatively to each other so that, during the etching, the elementary patterns join, causing an area including limiting (111) and (110) planes and non-limiting planes to appear between the patterns.

4. The method according to claim 3, characterized in that the elementary patterns are circles.

5. The method according to claim 3, characterized in that the elementary patterns are squares.

6. The method according to claim 5, characterized in that the squares are grouped parallel to each other so as to be inscribed in a square geometry, the sides of the squares not being orientated along the <110> direction of the substrate.

7. The method according to claim 5, characterized in that the squares are grouped parallel to each other according to a cross-shaped geometry, each square having two sides parallel to the <110> direction of the substrate, an overetching area (S1, S2, S3, S4) surrounding the periphery of each square.

8. The method according to claim 1, characterized in that the pattern is formed with at least a truncated square, two parallel sides of the square being parallel to the <110> direction of the substrate.

9. The method according to claim 1, characterized in that it comprises the deposition of a sacrificial layer (20) onto the substrate, the sacrificial layer conforming to the profile of the cell.

10. The method according to claim 9, characterized in that it comprises the deposition of a polymer layer (21) onto the sacrificial layer (20) and in that the polymer layer is etched in order to form circular holes (22) in the extension of the tips formed in the cell.

11. The method according to claim 10, characterized in that an insert is formed in a cell, from the bottom of the cell up to the level of an upper face of the polymer layer.

12. The method according to claim 11, characterized in that the sacrificial layer is etched in order to obtain detachment of the polymer layer.

13. The method according to claim 9, characterized in that a photoresist is insolated through a mask for forming holes (26) in the extension of tips (25) formed in the substrate.

14. The method according to claim 13, characterized in that an insert is formed in a hole formed in the photoresist.

15. The method according to claim 14, characterized in that the resin is removed by dissolving it in a solvent.

16. The method according to claim 15, characterized in that an insulating film is deposited on the sacrificial layer (20) and on the inserts (27).

17. The method according to claim 16, characterized in that plasma etching of the insulating film causes the tips of the inserts to protrude.

18. The method according to claim 17, characterized in that the insulating film provided with the inserts is detached from the sacrificial layer.

19. The method according to claim 11, characterized in that the inserts are formed by electrolytic growth, by evaporation or spraying.

20. The method according to claim 11, characterized in that the insert formed from the cell, has at the end opposite to its first end, at least one protruding tip and at least one recessed area, the protruding tip and the recessed area facing a recessed area and a protruding tip of the first end of the insert, respectively.

21. The method according to claim 20, characterized in that the insert formed from the cell has, at its first end, a protruding tip and at least two recessed areas.

22. The method according to claim 20, characterized in that the insert formed from the cell has, at its first end, a recessed area and at least two protruding tips.

23. The method according to claim 1, characterized in that the inserts are in nickel or copper.

24. The method according to claim 1, characterized in that the substrate is in silicone or silicon carbide.

25. The method according to claim 1, characterized in that it comprises a further etching step for increasing the tip height of the insert.
